(19) United States
(12) Patent Application Publication
(10) Pub. No.: US 2025/0251471 A1
(43) Pub. Date: Aug. 7, 2025

(54) DOUBLE BEAM OPTICALLY PUMPED MAGNETOMETER

(71) Applicant: Elta Systems Ltd., Ashdod (IL)

(72) Inventors: Igor SHCHERBACK, Beer Sheva (IL); Yossi ROSENZWEIG, Ashdod (IL); Dmitriy TOKAR, Beer Sheva (IL)

(21) Appl. No.: 19/040,413

(22) Filed: Jan. 29, 2025

(30) Foreign Application Priority Data
Feb. 5, 2024 (IL) 310659

(51) Int. Cl. G01R 33/032

(52) U.S. Cl. CPC G01R 33/032

(57) ABSTRACT

A magnetic field strength measurement system including: a vapor chamber holding alkali metal vapor; a light source unit configured to supply a first circularly polarized light beam and a second circularly polarized light beam to the vapor chamber, the first circularly polarized beam and the second circularly polarized beam having opposite circular polarization; a retroflection unit including at least one optical element and configured to return the first circularly polarized beam and the second circularly polarized beam to the vapor chamber, reversing direction, while maintaining polarization, of the first circularly polarized beam and the second circularly polarized beam; at least one detector configured to measure light associated with the first circularly polarized beam and the second circularly polarized beam emitted from the vapor chamber and to produce at least one measurement signal; circuitry configured to: provide a modulating signal to the light source unit, the modulating signal configured to modulate the first circularly polarized beam and the second circularly polarized second beam; receive the at least one measurement signal from the at least one detector; and determine a magnetic resonance frequency using one or both of the modulating signal and the at least one measurement signal.

### CROSS REFERENCE TO RELATED APPLICATIONS

This application claims the benefit of priority of Israeli Patent Application No. 310659, filed Feb. 5, 2024, the contents of which are incorporated herein by reference in their entirety.

### TECHNOLOGICAL FIELD

The present disclosure, in some embodiments, thereof, relates to optically pumped magnetometers (OPMs) and, more particularly, but not exclusively, to double or split beam OPMs.

### BACKGROUND ART

Acknowledgement of the above references herein is not to be inferred as meaning that these are in any way relevant to the patentability of the presently disclosed subject matter.

### GENERAL DESCRIPTION

Following is a non-exclusive list of some exemplary embodiments of the disclosure. The present disclosure also includes embodiments which include fewer than all the features in an example and embodiments using features from multiple examples, even if not listed below.

Example 1. A magnetic field strength measurement system comprising:
a vapor chamber holding alkali metal vapor;
a light source unit configured to supply a first circularly polarized light beam and a second circularly polarized light beam to said vapor chamber, said first circularly polarized beam and said second circularly polarized beam having opposite circular polarization;
a retroflection unit comprising at least one optical element and configured to return said first circularly polarized beam and said second circularly polarized beam to said vapor chamber, reversing direction, while maintaining polarization, of said first circularly polarized beam and said second circularly polarized beam;
at least one detector configured to measure light associated with said first circularly polarized beam and said second circularly polarized beam emitted from said vapor chamber and to produce at least one measurement signal;
circuitry configured to:
   provide a modulating signal to said light source unit, said modulating signal configured to modulate said first circularly polarized beam and said second circularly polarized second beam;
   receive said at least one measurement signal from said at least one detector; and
   determine a magnetic resonance frequency using one or both of said modulating signal and said at least one measurement signal.

Example 2. The system according to Example 1, wherein said at least one detector comprises:
a first detector configured to measure light associated with said first circularly polarized beam and emitted from said vapor chamber and to generate a first measurement signal; and
a second detector configured to measure light associated with said second circularly polarized beam and emitted from said vapor chamber and to generate a second measurement signal;
wherein said system comprises circuitry configured to combine said first measurement signal said second measurement signal.

Example 3. The system according to Example 2, wherein said circuitry comprises a differential amplifier configured to subtract said first and said second measurement signals from each other to provide a combined measurement signal.

Example 4. The system according to Example 1, comprising one or more optical element configured to direct said first circularly polarized beam and said second circularly polarized beam emitted from said vapor chamber towards said at least one detector which is configured to measure light associated with said first circularly polarized beam and said second circularly polarized beam emitted from said vapor chamber and to generate a combined measurement signal.

Example 5. The system according to Example 4, wherein said circuitry is configured to provide said modulation signal at a plurality of modulation frequencies;
wherein said combined measurement signal comprises a plurality of amplitudes, each amplitude associated with a frequency of said plurality of modulation frequencies.

Example 6. The system according to any one of Examples 3-5, wherein said circuitry comprises a lock-in amplifier configured to receive said combined measurement signal and said modulation signal and to produce a combined demodulated measurement signal.

Example 7. The system according to Example 6, wherein said demodulated combined measurement signal comprises a dispersive plot; and
wherein said circuitry is configured to extract said resonance frequency as a zero-crossing of said dispersive plot.

Example 8. The system according to Example 2, comprising circuitry configured to:
demodulate said first measurement signal and said second measurement signal using said modulating signal, to provide a first demodulated measurement signal and a second demodulated measurement signal.

Example 9. The system according to Example 8, wherein said circuitry is configured to provide said modulation signal at a plurality of modulation frequencies; wherein said first and said second demodulated measurement signals each comprise a plurality of amplitudes each amplitude associated with a frequency of said plurality of modulation frequencies.

Example 10. The system according to any one of Examples 8-9, wherein said circuitry is configured to demodulate said first measurement signal and said second measurement signal comprises:
a first lock-in amplifier configured to receive said first measurement signal, said modulating signal, and configured to output said first demodulated measurement signal; and
a second lock-in amplifier configured to receive said second measurement signal, said modulating signal, and configured to output said second demodulated measurement signal.

Example 11. The system according to Example 10, wherein said circuitry is configured to:
combine said first and said second demodulated measurement signals to provide a combined demodulated measurement signal; and
extract said resonance frequency from said combined demodulated measurement signal.

Example 12. The system according to Example 11, wherein said circuitry is configured to add said first and said second demodulated measurement signals.

Example 13. The system according to Example 9, wherein said circuitry is configured to subtract said first and said second demodulated measurement signals from each other.

Example 14. The system according to any one of Examples 11-13, wherein said combined demodulated measurement signal comprises a dispersive plot and where said circuitry is configured to extract said resonance frequency as a zero-crossing of a said dispersive plot.

Example 15. The system according to Example 6 or Example 11 or Example 14,wherein said circuitry is configured to use said combined demodulated measurement signal as feedback to said modulation signal to maintain said combined demodulated measurement signal at a set value, where said resonance frequency is extracted as a steady state frequency of said modulation signal.

Example 16. The system according to any one of Examples 2-15, wherein said light source unit comprises a laser light source configured to provide a laser light beam; and
a beam splitter configured to produce a first and a second about equal power laser light beams.

Example 17. The system according to Example 16, wherein said light source unit comprises:
a first polarizing beam splitter positioned to receive said first beam and configured to output a first linearly polarized beam; and
a second polarizing beam splitter positioned to receive said second beam and configured to output a second linearly polarized beam, polarization of said first and second linearly polarized beam being orthogonal.

Example 18. The system according to Example 17, wherein said light source unit comprises at least one circular polarizer positioned to receive said first and second linearly polarized beams and configured to circularly polarize said first and second linearly polarized beams to provide said first circularly polarized beam and said second circularly polarized beam which at least one circular polarizer positioned to provide said first circularly polarized beam and said second circularly polarized beam to said vapor chamber.

Example 19. The system according to any one of Examples 17-18, wherein said first and said second circularly polarized beams are fed to said vapor chamber in a first direction and where said retroflection unit is positioned to reverse a direction of said first and said second circularly polarized beams to provide first and second returning beams to said vapor chamber.

Example 20. The system according to any one of Examples 17-19, wherein said at least one detector comprises a photodiode.

Example 21. The system according to any one of Examples 19-20, wherein said first and said second returning beams, upon exiting said vapor chamber pass through said circular polarizer to become first and second linearly polarized returning beams;
wherein said first linearly polarized returning beam is received by said second polarizing beam splitter which directs said first linearly polarized returning beam to said second detector; and
wherein said second linearly polarized returning beam is received by said first polarizing beam splitter which directs said second linearly polarized returning beam to said first detector.

Example 22. The system according to any one of Examples 1-21, wherein said retroflection unit comprises at least two light diverting elements.

Example 23. The system according to Example 22, wherein each of said at least two light diverting elements comprise a reflecting prism or a mirror.

Example 24. The system according to any one of Examples 22-23, wherein said at least two light diverting elements comprises three light diverting elements.

Example 25. A method of measuring magnetic field strength comprising:
providing a modulating signal at a plurality of modulation frequencies;
directing a first and a second circularly polarized light beam into a vapor chamber of pumped alkali metal atoms in a first direction, where said first and said second circularly polarized light beams have opposite circular polarization helicity and are modulated according to said modulating signal;
reversing a direction, while maintaining polarization, of said first and said second circularly polarized beams upon exit from said vapor chamber to provide a first and second returning circularly polarized beam to said vapor chamber, said first and said second returning circularly polarized beams having opposite direction, and same circular polarization helicity as said first and said second circularly polarized beams respectively;
acquiring at least one measurement signal of:
   light emitted from said vapor chamber and associated with said first circularly polarized beam and said first returning circularly polarized beam; and light emitted from said vapor chamber and associated with said second circularly polarized beam and said second returning circularly polarized beam; and determining a magnetic resonance frequency from one or both of:
   said modulating signal; and
   said at least one measurement signal.

Unless otherwise defined, all technical and/or scientific terms used within this document have meaning as commonly understood by one of ordinary skill in the art/s to which the present disclosure pertains. Methods and/or materials similar or equivalent to those described herein can be used in the practice and/or testing of embodiments of the present disclosure, and exemplary methods and/or materials are described below. Regarding exemplary embodiments described below, the materials, methods, and examples are illustrative and are not intended to be necessarily limiting.

Some embodiments of the present disclosure are embodied as a system, method, or computer program product. For example, some embodiments of the present disclosure may take the form of an entirely hardware embodiment, an entirely software embodiment (including firmware, resident software, micro code, etc.) or an embodiment combining software and hardware aspects that may all generally be referred to herein as a “circuit,” “module” and/or “system.”

Implementation of the method and/or system of some embodiments of the present disclosure can involve performing and/or completing selected tasks manually, automatically, or a combination thereof. According to actual instrumentation and/or equipment of some embodiments of the method and/or system of the present disclosure, several selected tasks could be implemented by hardware, by software or by firmware and/or by a combination thereof, e.g., using an operating system.

For example, hardware for performing selected tasks according to some embodiments of the present disclosure could be implemented as a chip or a circuit. As software, selected tasks according to some embodiments of the present disclosure could be implemented as a plurality of software instructions being executed by a computational device e.g., using any suitable operating system.

In some embodiments, one or more tasks according to some exemplary embodiments of method and/or system as described herein are performed by a data processor, such as a computing platform for executing a plurality of instructions. Optionally, the data processor includes a volatile memory for storing instructions and/or data and/or a non-volatile storage e.g., for storing instructions and/or data. Optionally, a network connection is provided as well. User interface/s e.g., display/s and/or user input device/s are optionally provided.

Some embodiments of the present disclosure may be described below with reference to flowchart illustrations and/or block diagrams. For example illustrating exemplary methods and/or apparatus (systems) and/or and computer program products according to embodiments of the present disclosure. It will be understood that each step of the flowchart illustrations and/or block of the block diagrams, and/or combinations of steps in the flowchart illustrations and/or blocks in the block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart steps and/or block diagram block or blocks.

These computer program instructions may also be stored in a computer readable medium that can direct a computer (e.g., in a memory, local and/or hosted at the cloud), other programmable data processing apparatus, or other devices to function in a particular manner, such that the instructions stored in the computer readable medium can be used to produce an article of manufacture including instructions which implement the function/act specified in the flowchart and/or block diagram block or blocks.

The computer program instructions may also be run by one or more computational device to cause a series of operational steps to be performed e.g., on the computational device, other programmable apparatus and/or other devices to produce a computer implemented process such that the instructions which execute provide processes for implementing the functions/acts specified in the flowchart and/or block diagram block or blocks.

Some of the methods described herein are generally designed only for use by a computer, and may not be feasible and/or practical for performing purely manually, by a human expert. A human expert who wanted to manually perform similar tasks, might be expected to use different methods, e.g., making use of expert knowledge and/or the pattern recognition capabilities of the human brain, potentially more efficient than manually going through the steps of the methods described herein.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1A is a simplified schematic block diagram of a magnetometer system, according to some embodiments of the disclosure;

FIG. 1B is a cross sectional view of a portion of a retroflection unit, according to some embodiments of the disclosure;

FIG. 2 is a plot of theoretical magnetic resonance frequency with angle, according to some embodiments of the disclosure;

FIG. 3 is a method of measuring a magnetic field, according to some embodiments of the disclosure;

FIG. 4 is a simplified schematic of a magnetometer system, according to some embodiments of the disclosure;

FIG. 5 is a simplified schematic of a magnetometer system, according to some embodiments of the disclosure; and

FIG. 6 is a flow chart of a method of magnetic measurement, according to some embodiments of the disclosure.

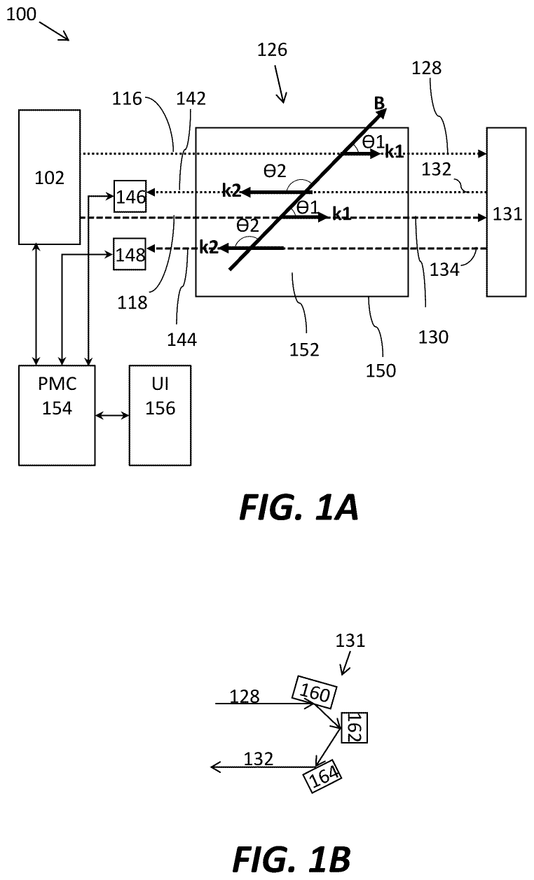

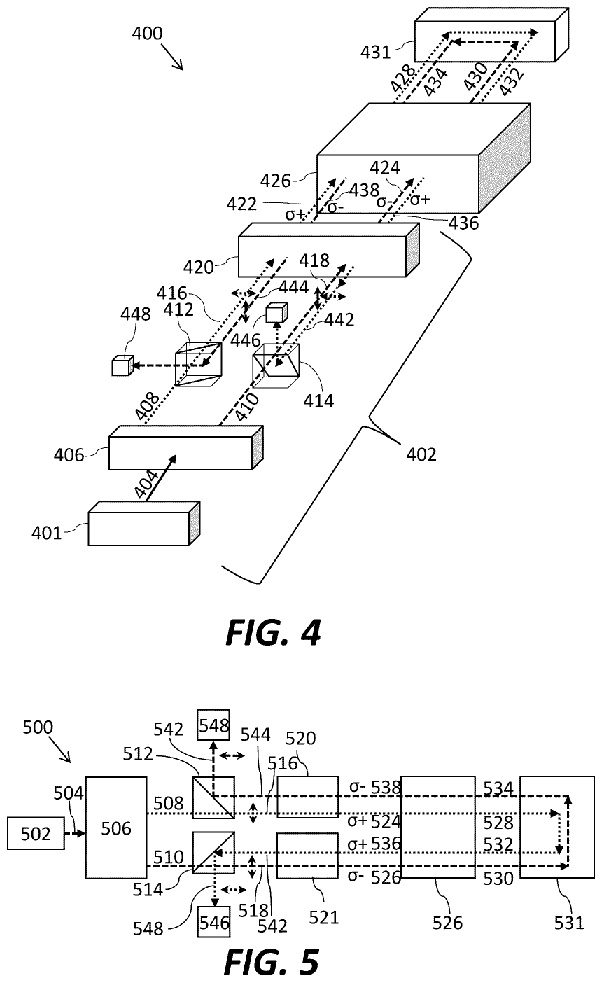

In some embodiments, although non-limiting, in different figures, like numerals are used to refer to like elements, for example, element 126 in FIG. 1A corresponding to element 426 in FIG. 4.

### DETAILED DESCRIPTION OF EMBODIMENTS

The present disclosure, in some embodiments, thereof, relates to optically pumped magnetometers (OPMs) and, more particularly, but not exclusively, to double or split beam OPMs.

### Overview

An aspect of some embodiments of the disclosure relates to optically pumped magnetometers (OPMs) and/or magnetic measurement systems where two beams of light, having opposite circular polarization are supplied to and traverse twice a transparent (e.g., glass) cell containing alkali metal vapor (herein termed a “vapor chamber” or a “vapor cell”). Where each beam, after traversing the vapor chamber in a “first pass” is returned to traverse the vapor chamber in an opposite direction, but while maintaining the same circular polarization, as a “second pass”. In some embodiments, effect on light output from the vapor chamber associated with each light beam (both first and second passes of the light beam) is measured. Where, in some embodiments, the measurements of the two beams are combined, the combined measurements then being used to determine a magnetic field. A potential benefit of this double beam, double pass scenario being reduction of heading error. Where heading error is defined, for example, as a change in magnetic field measurements of the magnetometer with change in angle between a direction of laser propagation through the vapor chamber and a direction of the magnetic field being measured. For example, where the magnetic field remains the same but an orientation of the magnetometer changes in space, without changing position (e.g. coordinates in space) of the magnetometer (e.g. rotation of the magnetometer about its center). For example, where the magnetic field changes direction, with respect to the magnetometer, without changing in magnitude.

A potential benefit of two passages of light through the vapor chamber, the first pass beam and second pass beam having the same polarization but different directions, is reduction in heading error when magnetic field is determined using measurement/s of light associated with both passes.

Without wanting to be bound by theory, it is theorized that passing a same helicity circular polarization beam twice in two directions through a vapor chamber compensates for non-linearity of Zeeman splitting. For example, compensating for differences in population distribution of Zeeman states associated with different angles between the laser propagation vector and magnetic field direction vector. As the population distribution changes, it is theorized, are opposite for the first and second pass beams, heading errors of the source beam and returning beam potentially cancel each other.

However, the first pass beams are expected to experience loss/es during passage through the vapor chamber and/or during interaction between optical elements as the transmitted first pass beam is directed backward as the reflected beam to become the second pass beam. The losses meaning, potentially, that for a single double pass beam, canceling of heading errors is limited.

An aspect of some embodiments of the disclosure relates to combining measurements of two beams each having first and second passes, where, for both beams, losses between each first pass beam and each second pass beam are associated with similar optical paths (e.g., interaction with the same vapor chamber and/or optical element/s). In some embodiments, given the helicities of the beams are opposite, the remaining heading error associated with attenuation of second pass beams is theorized to be similar but opposite, combination of measurements of the two beams, each having first and second passes, potentially having a further reduced heading error.

In some embodiments, open-loop measurements are performed where a modulation signal which is scanned through a range of modulation frequencies, modulates both the first and second beams. A demodulated measurement signal (as described hereinbelow) then displays a magnetic resonance frequency from which a magnetic field measurement may be determined.

In some embodiments, measurement of the two beams is separate where, for example, the first beam is measured by a first detector and the second beam is measured by a second detector. These measurements may then be combined prior to or after demodulation.

For example, in some embodiments, first and second measurement signals are subtracted from each other (e.g., at a differential amplifier) to provide a combined measurement signal which is then demodulated (e.g., by a lock-in amplifier receiving the modulation signal and the combined measurement signal). Magnetic resonance frequency may then be extracted from the demodulated combined measurement signal.

For example, in some embodiments, first and second measurement signals are individually demodulated, e.g., each by an associated lock-in amplifier, to produce a first and a second demodulated measurement signal. Where, in some embodiments, the first and second demodulated measurement signals are combined (e.g., by subtraction or addition) to provide a demodulated combined measurement signal. Magnetic resonance frequency is then, in some embodiments, extracted from the demodulated combined measurement signal. Alternatively, or additionally, in some embodiments, magnetic resonance frequencies are extracted from the first and second demodulated measurement signals respectively, and then combined to provide a single magnetic resonance frequency.

In some embodiments, the first and second beams are combined optically and measured at a single detector. A single combined measurement signal provided by the detector, in some embodiments, is then demodulated to provide a demodulated combined measurement signal, from which a magnetic resonance frequency may be extracted.

In some embodiments, closed loop measurements are performed, the magnetic resonance frequency is extracted from (e.g., as) a frequency of the modulation signal. Where controlling the modulation frequency and feedback of the combined demodulated measurement signal are used to maintain the combined demodulated measurement signal at a set value, the modulation frequency then providing an indication of the resonance frequency. The combined magnetic resonance frequency is obtained, in some embodiments, by using a combined demodulated measurement signal (e.g., according to one of the options described hereinabove) as feedback.

In some embodiments, the magnetometer (and/or magnetic measurement system) includes a single beam for both pumping and probing of the atoms in the vapor chamber.

Alternatively, in some embodiments, a first laser beam pumps the vapor chamber and a second laser beam, a “probe beam” is passed twice through the vapor chamber (e.g. a transmitted probe beam being reflected back into the vapor chamber).

In some embodiments, a light source unit is configured to provide two circularly polarized light beams having opposite circular polarization, where the light source unit is positioned on a first side of the vapor cell, and a retroflection unit is positioned on a second side of the cell. Where element/s of the retroreflection unit are aligned to reflect the source beams emitted from the vapor cell (the transmitted beams) to the vapor cell as second pass beams.

Where, in some embodiments, the retroflection unit comprises one or more optical elements configured to reverse a received beam direction while maintaining the beam's polarization, for example, the second pass beam, having a reversed direction to that of the first pass beam and circular polarization of the same helicity as the first pass beam. For example, where the k-vectors of the entering and reflected beams have opposite sign and where the entering and reflected beams have the same helicity e.g. both left-handed circular polarization, or both right-handed circular polarization. Where, in some embodiments, the light source unit e.g. including a linearly polarized laser source and optical element/s configured to convert the linearly polarized light into circularly polarized light.

A potential advantage of the double-pass configuration is, for a given optical pathway length within the vapor chamber, increased signal amplitude potentially providing higher signal to noise ratio (SNR) for the magnetic field measurement. For example, in comparison to a single pass configuration.

Increased SNR for given optical pathway length within the vapor chamber potentially allows reduction in size of the vapor chamber increased portability. Potentially, increased SNR enables one or more of reduction of the vapor chamber temperature and reduction of laser power of the source beam.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

### Exemplary System

FIG. 1A is a simplified schematic block diagram of a magnetometer system 100, according to some embodiments of the disclosure.

In some magnetometer system 100 (herein also termed “magnetometer” or “system”) includes a light source unit 102 configured to produce a first beam 116 and a second beam 118 of laser light, beams 116, 118 having opposite circular polarizations e.g. beam 116 being right-hand circularly polarized and beam 118 being left-hand circularly polarized. Where, in some embodiments light source unit 102 includes one or more feature of light source unit 402 FIG. 4.

In some embodiments, system 100 includes a vapor chamber 126 which, in some embodiments, includes a housing 150 which is formed of or includes transparent (e.g. to laser light) portion/s. Where light passing into vapor chamber 126 passes through a transparent portion of housing 150. In some embodiments, housing 150, holds a mixture 152 of vaporized alkali metal atoms and a buffer gas/es.

Exemplary alkali metals including any one of the Alkali metal atoms appearing in the first column of the periodic table (i.e., the Alkali metals Li, Na, K, Rb, Cs and Fr). Exemplary buffer gases include inert gasses, e.g., N₂, He, and mixtures thereof.

Magnetic field measurements, in some embodiments, are acquired by “pumping” the alkali vapor using circularly polarized laser light e.g., that emitted by source unit 102. Where the laser light enters and interacts with material 152 within vapor chamber 126. Pumping, it is theorized, causes the projection of the angular momentum for the alkali vapor atoms to accumulate in a “stretch state”, corresponding to Zeeman level mF=F.

Once the alkali atoms are pumped, light outputted 142, 144 from vapor chamber 126 is affected by the magnetic field: alkali atoms precess, it is theorized, under a magnetic field, according to the Larmor precession frequency, which frequency is associated with the Zeeman level of the atom precessing and the magnetic field strength.

In some embodiments (for example, once vapor chamber 126 is pumped) a portion of light passing into the vapor chamber passes through the vapor chamber 126.

In some embodiments, system 100 includes a retroflection unit 131 configured to reverse a direction of received light 128, 130, whilst maintaining a helicity of the light 128, 130. Where reversal in direction of first and second beam after their first pass through vapor chamber 126 directs the beams back towards vapor chamber 136 to perform a “second pass” through vapor chamber 126. Where helicity of the light beams received 128, 130 is the same as those beams returned 132, 134 to vapor chamber 126 respectively by retroflection unit 131 e.g., if first light beam 128 has right circular polarization light, returned first light beam 132 has right circular polarization light.

Exemplary retroreflection unit 110 implementations are described with reference to FIG. 1B hereinbelow.

In some embodiments, magnetometer 100 includes at least one optical sensor (also herein termed “detector”). In some embodiments, magnetometer includes two detectors, a first detector 146 and a second detector 148. Where detector/s 146, 148 include, in some embodiments, one or more optical sensor configured to sense light emanating from vapor chamber 126. In some embodiments, magnetometer 100 is configured so that first detector 146 detects first beam light 142 and second detector 148 detects second beam light 144. In embodiments including a single detector, one or more element (not illustrated) directs both light beams 142, 144 to the single detector and/or combines the two beams 142, 144 prior to detection at the signal detector.

The detector/s, for example, are configured to provide an electrical signal corresponding to received light. In some embodiments, the optical sensor/s include one or more photodiode. Where the photodiode/s are configured to output an electrical signal corresponding to light sensed by the photodiode.

To measure the magnetic field, in some embodiments, laser light beams 116, 118 are modulated, for example, by a modulation signal (e.g. provided by a current supply signal to a laser of light source unit 102).

In some embodiments, a modulation signal is scanned through a range of frequencies (continuously or with a plurality of discrete frequency values). Where measurement signals (e.g. as provided by detectors 146, 148) are demodulated, and a resonance frequency being extracted from the demodulated measurement signal.

Alternatively, or additionally, in some embodiments, frequency of a modulation signal is controlled using feedback of the demodulated signal, where feedback is applied to maintain the demodulated signal at a set value (e.g. zero, corresponding to zero-crossing resonance frequency of the dispersive demodulation). Where the controlled frequency of the modulation signal is interpreted as corresponding to the resonance frequency, e.g. in a steady state. When the magnetic field changes, the demodulated value changes to a higher or lower value. Then, associated with the feedback, the modulation frequency changes until the demodulated signal reaches the set value again (e.g., zero).

Modulation of the modulation signal, in some embodiments, includes frequency modulation e.g. the laser's frequency is changing with time e.g. according to a frequency of the modulation signal. In some embodiments, frequency modulation is employed when the modulation signal is directly connected to a driver of the laser.

In some embodiments, modulation of the modulation signal is via amplitude modulation e.g. where the laser amplitude is changed with time. For example, turned on and off at the modulation frequency e.g. by a chopper element which blocks the laser light on and off.

In some embodiments, modulation of the modulation signal is via polarization modulation e.g. where the laser circular polarization is changed with time. For example, switched from left to right polarization at the modulation frequency.

Illustrated in FIG. 1 are the beams 116, 118, 132, 134 passing through vapor chamber 126 and an exemplary magnetic field direction B where first pass beams 116, 118 have direction k1 at an angle of θ1 to the magnetic field and second pass beams 132, 134 have direction k2 at an angle of θ2 (i.e., θ₂=θ₁+180) to the magnetic field. Heading error, e.g., as described previously, is variation of magnetic field measurements with respect to the angle of the laser beam with respect to the magnetic field to be measured B.

In some embodiments, magnetometer system 100 includes processing and memory circuitry (PMC) 154. Where, in some embodiments, PMC 154 receives sensor measurement data e.g. from one or more detector/s 146, 148. Where, in some embodiments, PMC 154 processes sensor measurements and, in some embodiments, generates control signals for elements controlled by PMC 154 e.g. light source 102.

In some embodiments, measurement signals (e.g. provided by detectors 146, 148) are demodulated (e.g. using the modulation signal e.g. at PMC 154) to provide one or more demodulated measurement signal output with modulation frequency.

In some embodiments, signals from detection of beams 142, 144 are combined e.g., prior to demodulation, for example, in order to provide measurement of magnetic field with reduced heading error.

In embodiments, detection of beams 142, 144, is separate, e.g., by first and second detectors 146, 148. Where, in some embodiments, the signals from first and second detectors 146, 148 are subtracted from each other. Where, in some embodiments, the signals are added to each other.

In embodiments where a single detector is used to detect both beams 142, 144, the combined detection summing the effect of beams 142, 144.

Where, in some embodiments, demodulated measurement signals include one or more of an in-phase signal, a quadrature signal, a phase signal, and an amplitude signal. In some embodiments, demodulated measurement signal/s are generated by a lock-in amplifier (e.g. as an output thereof).

In embodiments where magnetometer 100 includes two detectors 146, 148, in some embodiments, two lock-in amplifiers are used. Where, in some embodiments, for each lock-in amplifier, inputs include a measurement signal (from a single detector) and the modulation signal e.g., as a reference. The lock-in amplifier's output including one or more of an in-phase signals, a quadrature signal, a phase signal, and an amplitude signal. Lock-in amplifier output with modulation frequency plots are also herein termed “magnetic resonance plots” and “line-shapes”. In some embodiments, the two plots, one for each detector and associated lock-in amplifier are combined (e.g., summed or subtracted from each other) and the magnetic field strength is extracted as resonance frequency/ies of the combined magnetic resonance plot.

In some embodiments, a single lock-in amplifier is used e.g., where a single detector is used, e.g., where two signals from the two detectors are combined (e.g., by a differential amplifier) prior to being fed into the lock-in amplifier. Where inputs to a single lock-in amplifier are, for example, the single detector signal or combined detector signal, and the modulation signal. Magnetic field strength may then be extracted as resonance frequency/ies of the resonance plot/s produced from the output of the single lock-in amplifier.

In some embodiments, system 100 includes one or more user interface (UI) 156. Where, in some embodiments, UI 156 is configured to receive instruction/s and/or data (e.g. from a user) and transfer them to PMC 154. Where, in some embodiments, UI 156 is configured to receive data from PMC 154 and, for example, display the data e.g., to user/s. The data displayed, for example, including determined measurement/s of magnetic field.

FIG. 1B is a cross sectional view of a portion of a retroflection unit 131, according to some embodiments of the disclosure.

In some embodiments, retroreflection unit 131 includes at least two light diverting elements 160, 164 (e.g. each light diverting element including a mirror reflector or prism). Where the at least two light diverting elements have together zero relative phase retardance between S and P polarization of received light 128 with respect to the reflected light 132. In some embodiments, retroreflection unit 131 includes one or more additional light diverting elements 162 (e.g., retroreflection unit 131, includes at least three light diverting elements) in order to cancel out the accumulated relative phase change e.g., to maintain the relative phase between S and P polarization components.

In some embodiments, retroflection unit 131 includes a single element which is configured to retroflect without changing helicity, e.g., a single monolithic element having different portions with different optical properties.

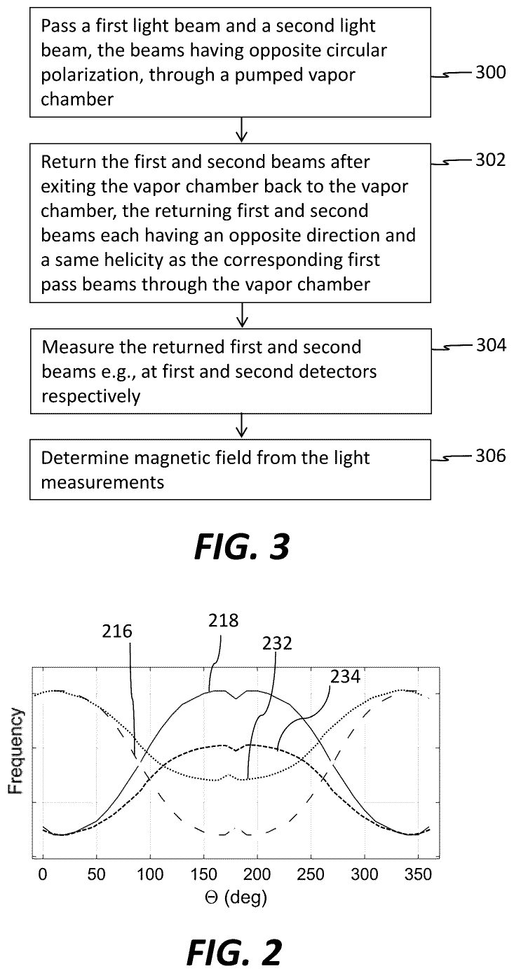

FIG. 2 is a plot of theoretical magnetic resonance frequency with angle, according to some embodiments of the disclosure.

Annotated on FIG. 2 are heading errors 216, 218, 232, 234 (e.g., differences in magnetic resonance frequency) corresponding to beam passes 116, 118, 132, 134 respectively.

Visible in FIG. 2 is how, if the overall effect of first beam (plots 216, 232) is added to the effect of the second beam (plots 218, 234) differences in magnetic resonance frequency are reduced (flattened) corresponding to a reduced heading error.

FIG. 3 is a method of measuring a magnetic field, according to some embodiments of the disclosure.

At 300, in some embodiments a first light beam and a second light beam, where both light beams are circularly polarized, but with opposite helicities e.g., if first light beam is right-hand circularly polarized, then second light beam is left-hand circularly polarized.

At 302, in some embodiments, the first and second beams are returned to the vapor chamber, after their exit from the chamber. Where the returned beams have opposite direction and the same helicity circular polarization as the beams which passed through the vapor chamber.

At 304, in some embodiments, the returned first and second beams, after exit from the vapor chamber, are measured e.g., each by a detector.

At 306, in some embodiments, the magnetic field is determined using the light measurements acquired at step 304, for example, where modulation signal/s are employed e.g., as described regarding FIG. 1.

For example, where two measurement signals from two detectors (e.g., detectors 146, 148 FIG. 1) are added or subtracted from each other e.g., prior to demodulation which is performed using the modulation signal/s. Where, in some embodiments, magnetic field is extracted as a zero crossing of a line-shape.

FIG. 4 is a simplified schematic of a magnetometer system 400, according to some embodiments of the disclosure.

In some embodiments, magnetometer system 400 (herein also termed “magnetometer” or “system”) includes a light source unit 402 which includes one or more feature illustrated or described regarding light source 102 FIG. 1.

In some embodiments, light source unit 402 includes one or more of a laser 401, an optical splitter 406, polarization beam splitters 412, 414, and a circular polarizer 420 (e.g., a λ/4 waveplate).

In some embodiments, laser 401 emits laser light 404, laser 401, for example, including a VCSEL laser, or DFB/DBR laser.

In some embodiments, laser 401 is configured (e.g., positioned and/or orientated) to direct emitted light 404 to optical splitter 406. Where, in some embodiments, optical splitter 406 is configured to split received light 404 into two beams 408, 410 having a same optical power (or, where optical power of the beams differs by at most 1%).

In some embodiments, beams 408, 410 then proceed to splitters 412, 414 respectively. In some embodiments (e.g., where linear polarization of beams 408, 410 is high) splitters each include a half wave plate retarder. In some embodiments, splitters 412, 414 are polarization beam splitters (PBSs) e.g., each including a polarizer and a half wave plate. Where PBSs 412, 414, linearly polarize beams 408, 410 to have orthogonal polarizations (e.g., as illustrated by arrows adjacent to beams 416, 418 exiting the respective PBAs 412, 414). A first PBS 412 polarizing first beam 408, and a second PBS 414 polarizing second beam 410. FIG. 4 illustrates an exemplary embodiment, where the two polarizations are both orthogonal to each other and to a direction of the beams. Other orthogonal polarizations are envisioned and encompassed by the disclosure e.g., that illustrated in FIG. 5.

In some embodiments, the first and second linearly polarized beams 416, 418 pass to circular polarizer 420 which transforms the beams into circularly polarized beams 422, 424 having opposite helicity. Illustrate in FIG. 4 are helicities of an exemplary embodiment, where first circularly polarized beam 422 is right hand circularly polarized and second circularly polarized beam 424 is left hand circularly polarized.

In some embodiments, two oppositely polarized beams 422, 424 then pass to be received by vapor cell 426. First pass beams 428, 430 (beams 422, 424 having passed through vapor cell 426) then pass to a retroreflection unit 431, which returns first pass beams 428, 430 to vapor cell 426 as returned beams 432, 434, having an opposite direction but same helicity as the first pass beams 428, 430.

Returned beams 432, 434, after traversing vapor cell for a second time, emerge as second pass beams 436, 438 (having respectively same helicity as circularly polarized beams 422, 424 e.g., as illustrated in FIG. 4).

Second pass beams 436, 438 then pass through circular polarizer 420 to become linearly polarized second pass beams 442, 444 having orthogonal polarizations (e.g., as illustrated by arrows on the beams in FIG. 4).

Linearly polarized second pass beams 442, 444 are then directed away from a plane and/or axis of the beam travel by PBSs 412, 414 respectively to be detected by detectors 446, 448. FIG. 4 illustrates an embodiment where second detector 448 is within an optical plane including the beam travel and other optical components whereas first detector 446 is orthogonal to the plane of first and second beams (e.g., XY plane).

In some embodiments, system includes one or both of a PMC and a UI (not illustrated in FIG. 4) each including, for example, one or more feature as illustrated in and/or described regarding PMC 154, and UI 156 FIG. 1.

FIG. 5 is a simplified schematic of a magnetometer system 500, according to some embodiments of the disclosure.

In some embodiments, each of a light unit 502, a beam splitter 506, beams 508, 510, linearly polarized beams 516, 518, circularly polarized beams 524, 526, vapor chamber 526, first pass beams 528, 530, retroreflection unit 531, returned beams 532, 534, second pass beams 536, 538, linearly polarized second pass beams 542, 544, and detectors 546, 548, include one or more feature as illustrated in and/or describing similarly numbered elements 402, 406, 408, 410, 426, 431 of FIG. 4.

However, in comparison to FIG. 4, FIG. 5 illustrates an exemplary embodiment where beam splitters 512, 514 and linear polarization of beams 516, 518 (e.g. as illustrated by double headed arrows) are configured so that detectors 546, 548 are both in a plane of other optical elements, a potential benefit being increased compactness of magnetometer system 500. For beams to be correctly circularly polarized, e.g., prior to entry to vapor chamber 526, system 500 includes two circular polarizers 520, 521.

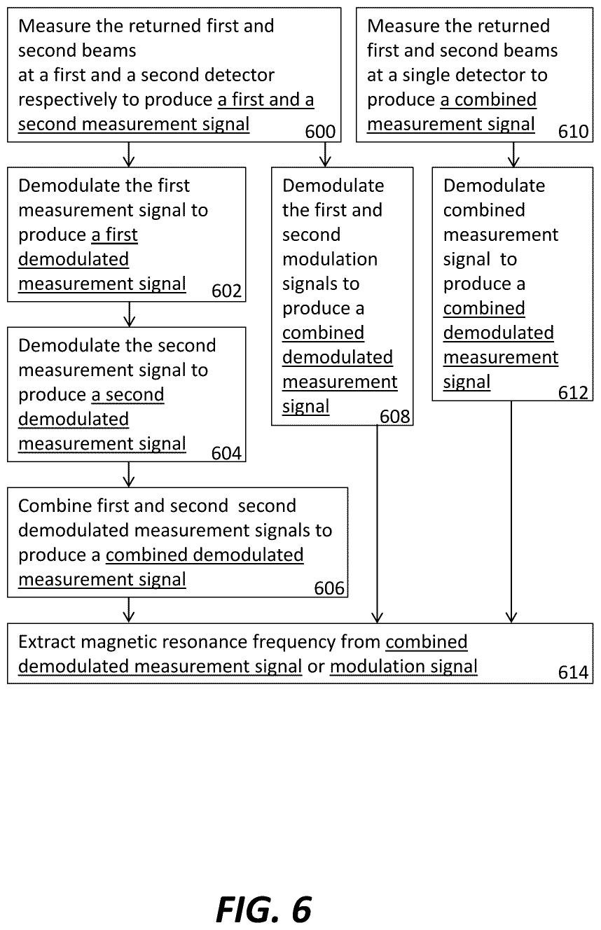

FIG. 6 is a flow chart of a method of magnetic measurement, according to some embodiments of the disclosure.

FIG. 6 illustrates exemplary options for combination of measurement of the two beams and extraction of magnetic resonance frequencies therefrom.

At 600, in some embodiments, the returned first and second beams are measured at a first and a second detector respectively to produce a first and a second measurement signal.

At 602, in some embodiments, the first measurement signal is demodulated to produce a first demodulated measurement signal.

At 604, in some embodiments, the second measurement signal is demodulated to produce a second demodulated measurement signal.

At 606, in some embodiments, the first and second demodulated measurement signals are combined (e.g., by subtraction or addition) to provide a combined demodulated measurement signal.

At 608, in some embodiments, a magnetic resonance frequency is extracted from the combined demodulated measurement signal (or, in closed loop operation, from the frequency of the modulation signal).

In some embodiments, for example, alternatively to steps 602-606, at 608, in some embodiments, the first and second modulation signals are demodulated together to produce a combined demodulated measurement signal. Where, in some embodiments, the first and second measurement signals are combined prior to demodulation (for example, by subtraction of the signals from each other e.g., at a differential amplifier).

In some embodiments, alternatively to step 600, a single detector is used to measure both first and second beams (e.g., where optical component/s are used to direct both beams to the single detector).

At step 612, in some embodiments, the combined measurement signal produced by the single detector is then demodulated and, at step 614, a magnetic resonance frequency is extracted.

### General

As used within this document, the term “about” refers to ±20%

The terms “comprises”, “comprising”, “includes”, “including”, “having” and their conjugates mean “including but not limited to”.

The term “consisting of” means “including and limited to”.

As used herein, singular forms, for example, “a”, “an” and “the” include plural references unless the context clearly dictates otherwise.

Within this application, various quantifications and/or expressions may include use of ranges. Range format should not be construed as an inflexible limitation on the scope of the present disclosure. Accordingly, descriptions including ranges should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within the stated range and/or subrange, for example, 1, 2, 3, 4, 5, and 6. Whenever a numerical range is indicated within this document, it is meant to include any cited numeral (fractional or integral) within the indicated range.

It is appreciated that certain features which are (e.g., for clarity) described in the context of separate embodiments, may also be provided in combination in a single embodiment. Where various features of the present disclosure, which are (e.g., for brevity) described in a context of a single embodiment, may also be provided separately or in any suitable sub-combination or may be suitable for use with any other described embodiment. Features described in the context of various embodiments are not to be considered essential features of those embodiments, unless the embodiment is inoperative without those elements.

Although the present disclosure has been described in conjunction with specific embodiments thereof, it is evident that many alternatives, modifications, and variations will be apparent to those skilled in the art. Accordingly, this application intends to embrace all such alternatives, modifications and variations that fall within the spirit and broad scope of the appended claims.

All references (e.g., publications, patents, patent applications) mentioned in this specification are herein incorporated in their entirety by reference into the specification, e.g., as if each individual publication, patent, or patent application was individually indicated to be incorporated herein by reference. Citation or identification of any reference in this application should not be construed as an admission that such reference is available as prior art to the present disclosure. In addition, any priority document(s) and/or documents related to this application (e.g., co-filed) are hereby incorporated herein by reference in its/their entirety.

Where section headings are used in this document, they should not be interpreted as necessarily limiting

1. A magnetic field strength measurement system comprising:
a vapor chamber holding alkali metal vapor;
a light source unit configured to supply a first circularly polarized light beam and a second circularly polarized light beam to said vapor chamber, said first circularly polarized beam and said second circularly polarized beam having opposite circular polarization;
a retroflection unit comprising at least one optical element and configured to return said first circularly polarized beam and said second circularly polarized beam to said vapor chamber, reversing direction, while maintaining polarization, of said first circularly polarized beam and said second circularly polarized beam;
at least one detector configured to measure light associated with said first circularly polarized beam and said second circularly polarized beam emitted from said vapor chamber and to produce at least one measurement signal;
circuitry configured to:
provide a modulating signal to said light source unit, said modulating signal configured to modulate said first circularly polarized beam and said second circularly polarized second beam;
receive said at least one measurement signal from said at least one detector; and
determine a magnetic resonance frequency using one or both of said modulating signal and said at least one measurement signal.

2. The system according to claim 1, wherein said at least one detector comprises:
a first detector configured to measure light associated with said first circularly polarized beam and emitted from said vapor chamber and to generate a first measurement signal; and
a second detector configured to measure light associated with said second circularly polarized beam and emitted from said vapor chamber and to generate a second measurement signal;
wherein said system comprises circuitry configured to combine said first measurement signal said second measurement signal.

3. The system according to claim 2, wherein said circuitry comprises a differential amplifier configured to subtract said first and said second measurement signals from each other to provide a combined measurement signal.

4. The system according to claim 1, comprising one or more optical element configured to direct said first circularly polarized beam and said second circularly polarized beam emitted from said vapor chamber towards said at least one detector which is configured to measure light associated with said first circularly polarized beam and said second circularly polarized beam emitted from said vapor chamber and to generate a combined measurement signal.

5. The system according to claim 4, wherein said circuitry is configured to provide said modulation signal at a plurality of modulation frequencies;
wherein said combined measurement signal comprises a plurality of amplitudes, each amplitude associated with a frequency of said plurality of modulation frequencies.

6. The system according to claim 5, wherein said circuitry comprises a lock-in amplifier configured to receive said combined measurement signal and said modulation signal and to produce a combined demodulated measurement signal.

7. The system according to claim 6, wherein said demodulated combined measurement signal comprises a dispersive plot; and
wherein said circuitry is configured to extract said resonance frequency as a zero-crossing of said dispersive plot.

8. The system according to claim 2, comprising circuitry configured to:
demodulate said first measurement signal and said second measurement signal using said modulating signal, to provide a first demodulated measurement signal and a second demodulated measurement signal;
wherein said circuitry is configured to provide said modulation signal at a plurality of modulation frequencies;
wherein said first and said second demodulated measurement signals each comprise a plurality of amplitudes each amplitude associated with a frequency of said plurality of modulation frequencies.

9. The system according to claim 8, wherein said circuitry is configured to demodulate said first measurement signal and said second measurement signal comprises:
a first lock-in amplifier configured to receive said first measurement signal, said modulating signal, and configured to output said first demodulated measurement signal; and
a second lock-in amplifier configured to receive said second measurement signal, said modulating signal, and configured to output said second demodulated measurement signal.

10. The system according to claim 9, wherein said circuitry is configured to:
combine said first and said second demodulated measurement signals to provide a combined demodulated measurement signal; and
extract said resonance frequency from said combined demodulated measurement signal.

11. The system according to claim 10, wherein said circuitry is configured to add said first and said second demodulated measurement signals; or
to subtract said first and said second demodulated measurement signals from each other.

12. The system according to claim 11, wherein said combined demodulated measurement signal comprises a dispersive plot and where said circuitry is configured to extract said resonance frequency as a zero-crossing of a said dispersive plot.

13. The system according to claim 6, wherein said circuitry is configured to use said combined demodulated measurement signal as feedback to said modulation signal to maintain said combined demodulated measurement signal at a set value, where said resonance frequency is extracted as a steady state frequency of said modulation signal.

14. The system according to claim 2, wherein said light source unit comprises a laser light source configured to provide a laser light beam; and
a beam splitter configured to produce a first and a second about equal power laser light beam.

15. The system according to claim 14, wherein said light source unit comprises:
a first polarizing beam splitter positioned to receive said first beam and configured to output a first linearly polarized beam; and
a second polarizing beam splitter positioned to receive said second beam and configured to output a second linearly polarized beam, polarization of said first and second linearly polarized beam being orthogonal.

16. The system according to claim 15, wherein said light source unit comprises at least one circular polarizer positioned to receive said first and second linearly polarized beams and configured to circularly polarize said first and second linearly polarized beams to provide said first circularly polarized beam and said second circularly polarized beam which at least one circular polarizer positioned to provide said first circularly polarized beam and said second circularly polarized beam to said vapor chamber.

17. The system according to claim 15, wherein said first and said second circularly polarized beams are fed to said vapor chamber in a first direction and where said retroflection unit is positioned to reverse a direction of said first and said second circularly polarized beams to provide first and second returning beams to said vapor chamber.

18. The system according to claim 17, wherein said first and said second returning beams, upon exiting said vapor chamber pass through said circular polarizer to become first and second linearly polarized returning beams;
wherein said first linearly polarized returning beam is received by said second polarizing beam splitter which directs said first linearly polarized returning beam to said second detector; and
wherein said second linearly polarized returning beam is received by said first polarizing beam splitter which directs said second linearly polarized returning beam to said first detector.

19. The system according to claim 1, wherein said retroflection unit comprises at least two light diverting elements.

20. A method of measuring magnetic field strength comprising:
providing a modulating signal at a plurality of modulation frequencies;
directing a first and a second circularly polarized light beam into a vapor chamber of pumped alkali metal atoms in a first direction, where said first and said second circularly polarized light beams have opposite circular polarization helicity and are modulated according to said modulating signal;
reversing a direction, while maintaining polarization, of said first and said second circularly polarized beams upon exit from said vapor chamber to provide a first and second returning circularly polarized beam to said vapor chamber, said first and said second returning circularly polarized beams having opposite direction, and same circular polarization helicity as said first and said second circularly polarized beams respectively;
acquiring at least one measurement signal of:
light emitted from said vapor chamber and associated with said first circularly polarized beam and said first returning circularly polarized beam; and
light emitted from said vapor chamber and associated with said second circularly polarized beam and said second returning circularly polarized beam; and
determining a magnetic resonance frequency from one or both of:
said modulating signal; and
said at least one measurement signal.
